(19) United States
(12) Patent Application Publication
(10) Pub. No.: US 2024/0421265 A1
(43) Pub. Date: Dec. 19, 2024

(54) DISPLAY DEVICE

(71) Applicant: Japan Display Inc., Tokyo (JP)

(72) Inventors: Toshihiro YAJIMA, Tokyo (JP); Michihide SHIBATA, Tokyo (JP); Takashi OTA, Tokyo (JP)

(73) Assignee: Japan Display Inc., Tokyo (JP)

(21) Appl. No.: 18/673,352

(22) Filed: May 24, 2024

(30) Foreign Application Priority Data
Jun. 14, 2023 (JP) 2023-097411

(51) Int. Cl. H01L 33/50; G02F 1/13357; H01L 25/075

(52) U.S. Cl. CPC H01L 33/502; G02F 1/133603; H01L 25/0753; H01L 33/505; H01L 33/508

(57) ABSTRACT

The purpose is to reduce a color shift around an ultraviolet LED in a backlight using the ultraviolet LED and a QD sheet, viewed in a plane. The structure is: A display device having a display panel and a backlight, the backlight including a light source in which ultraviolet LEDs are arranged in a plane and in a matrix with a first interval, and a QD sheet covering the light source; the QD sheet being dispersed with red quantum dots, green quantum dots, and blue quantum dots, emitting light in response to ultraviolet light, the QD sheet having a first region and a second region arranged in a ring shape to surround the ultraviolet LED in a plan view, more of the red quantum dots, the green quantum dots, or the blue quantum dots being dispersed in the second region than in the first region.

### CROSS-REFERENCE TO RELATED APPLICATION

The present application claims priority from Japanese Patent Application JP 2023-097411 filed on Jun. 14, 2023, the content of which is hereby incorporated by reference into this application.

### BACKGROUND OF THE INVENTION

### (1) Field of the Invention

This invention relates to a direct-type backlight with a large number of light emitting diodes (LEDs) arranged on a flat surface, and to a display device using this backlight.

### (2) Description of the Related Art

As a backlight for display areas of liquid crystal display (LCD) devices, etc., it generally utilizes a number of single-color LEDs or ultraviolet LEDs arranged on a flat surface and a color conversion sheet covering the LEDs to obtain white light. The following is an example of a LCD.

In a LCD device, a thin-film transistor (TFT) substrate on which pixel electrodes and TFTs, etc. are formed in matrix form is placed opposite the opposite substrate, and a liquid crystal layer is sandwiched between the TFT substrate and the opposite substrate. An image is formed by controlling the transmittance of light by the liquid crystal molecules on a pixel-by-pixel basis.

Since the LCD panel itself does not emit light, a backlight is necessary. On the other hand, white light is needed for the backlight. There are two methods: one is to mix light emitted from LEDs of three colors to obtain the white light, and the other is to convert light from LEDs of one color to white using a light conversion sheet. In both methods, the problem of completely mixing light to obtain the white light exists.

Patent document 1 describes a configuration in which a number of single-color LEDs are arranged on a flat surface, and for each LED, a quantum dot (QD) box with a QD sheet on the inner wall and an aperture that radiates light upward. In the configuration of Document 1, the light from the LEDs is converted by the QD sheet, and the light from the LEDs and the converted light are sufficiently mixed in the QD box to emit the white light through the aperture.
Patent document 1: Japanese Patent Application Laid Open No. 2018-198187

### SUMMARY OF THE INVENTION

There are two methods of obtaining white color in backlight: one is to use a single-color LED and obtain white color by means of a color conversion sheet, and the other is to use an ultraviolet LED and obtain white visible light by means of a color conversion sheet such as a QD sheet, for example.

Blue LEDs are used as monochromatic LEDs. For example, mixing blue and yellow can produce a pseudo-white color. Therefore, if a color conversion sheet that converts blue to yellow is placed in the direction of the output of the blue LED, white light produced by mixing blue with yellow is emitted from the color conversion sheet. In this method, the ratio of blue light to yellow light may change in the light emitted from the color conversion sheet depending on the direction of light from the LEDs. When this happens, color irregularities occur.

In the case of ultraviolet LEDs (UV LEDs), for example, QDs that emit red, green, and blue light when exposed to ultraviolet light are dispersed in the color conversion sheet. However, because the conversion efficiency of red, green, and blue QDs for the same UV light is different, the white color may be uneven due to the difference in the light path through the QD sheet. The problem of the present invention is to realize a backlight that can reduce color irregularities due to differences in the light source emission direction and obtain uniform white color in a configuration that uses UV LEDs as the light source and a color conversion sheet such as a QD sheet.

The present invention solves the above problem, and the main specific means are as follows.

(1) A display device including a display panel and a backlight, the backlight including a light source in which ultraviolet light emitting diodes are arranged in a plane and in a matrix with a first spacing, and a color conversion sheet covering the light source, the color conversion sheet being dispersed with red quantum dots that emit red when exposed to ultraviolet light, green quantum dots that emit green when exposed to the ultraviolet light, and blue quantum dots that emit blue when exposed to the ultraviolet light, the color conversion sheet having a first region and a second region arranged in a ring shape to surround the ultraviolet light emitting diode in a plane view, more of the red quantum dots, the green quantum dots, or the blue quantum dots are dispersed in the second region than in the first region.

(2) The display device as described in (1), characterized in that, in the second region, the red quantum dots are dispersed more than in the first region.

(3) The display device as described in (1), characterized in that, in the second region, the green quantum dots are dispersed more than in the first region.

(4) The display device as described in (1), characterized in that, in the second region, the blue quantum dots are dispersed more than in the first region.

(5) The display device as described in (1), characterized in that an outer radius of the ring is equal to or less than ¼ of the first spacing.

(6) The display device as described in (1), characterized in that any of the red quantum dots, the green quantum dots, and the blue quantum dots in the second area have a distribution, and a peak of the distribution is located outside a center of a width of the ring.

(7) A display device including a display panel and a backlight, the backlight including a light source in which ultraviolet light emitting diodes are arranged in a plane and in a matrix with a first spacing, and a color conversion sheet covering the light source, the color conversion sheet being dispersed with red quantum dots that emit red when exposed to ultraviolet light, green quantum dots that emit green when exposed to the ultraviolet light, and blue quantum dots that emit blue when exposed to the ultraviolet light, the color conversion sheet having a first area and a second area arranged in a circular pattern to cover the ultraviolet light emitting diode in a plane view, more of the red quantum dots, the green quantum dots, or the blue quantum dots are dispersed in the second region than in the first region.

### BRIEF DESCRIPTION OF THE DRAWINGS

FIG. 1 is a plan view of a liquid crystal display device;

FIG. 2 is a cross-sectional view of the liquid crystal display device;

FIG. 3 is a plan view of an example of segments in a liquid crystal display device;

FIG. 4 is a plan view of four segments in a backlight;

FIG. 5 is A-A cross-sectional view of FIG. 4;

FIG. 6 is an example of quantum dots;

FIG. 7 is a plan view illustrating a yellow shift;

FIG. 8 is a cross-sectional view illustrating the yellow shift;

FIG. 9 is a plan view illustrating a magenta shift;

FIG. 10 is a cross-sectional view illustrating the magenta shift;

FIG. 11 is a plan view illustrating a cyan shift;

FIG. 12 is a cross-sectional view illustrating the cyan shift;

FIG. 13 is a plan view illustrating the yellow shift in Example 1;

FIG. 14 is a cross-sectional view of Example 1 illustrating the yellow shift;

FIG. 15 is a plan view of how to prevent the magenta shift in Example 1;

FIG. 16 is a cross-sectional view of Example 1 to prevent the magenta shift;

FIG. 17 is a plan view of Example 1 to prevent the cyan shift;

FIG. 18 is a cross-sectional view of Example 1 to prevent the cyan shift;

FIG. 19 is a plan view of Example 2 to prevent the yellow shift;

FIG. 20 is a cross-sectional view of Example 2 to prevent the yellow shift;

FIG. 21 is a plan view of Example 2 to prevent the magenta shift;

FIG. 22 is a cross-sectional view of Example 2 to prevent the magenta shift;

FIG. 23 is a plan view of Example 2 to prevent the cyan shift;

FIG. 24 is a cross-sectional view of Example 2 to prevent the cyan shift;

FIG. 25 is a cross-sectional view of another example of the backlight; and

FIG. 26 is a cross-sectional view of another example of the backlight.

### DETAILED DESCRIPTION OF THE PREFERRED EMBODIMENTS

A backlight of the present invention can be used for various display devices. Since liquid crystal display (LCD) devices are representative among display devices that use back lights, the present invention will be explained by means of examples in line with LCDs below.

### Embodiment 1

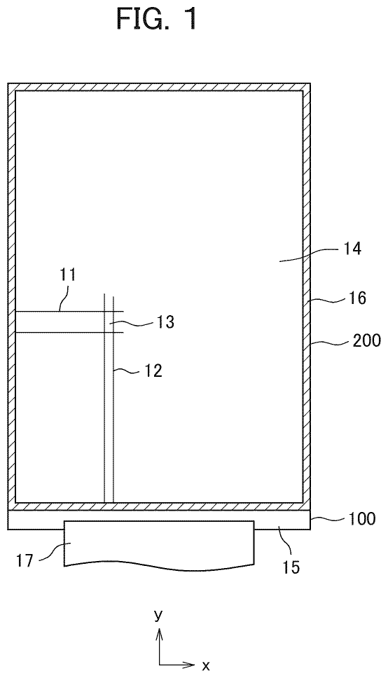

FIG. 1 is a plan view of an example of a LCD device. In FIG. 1, a thin-film transistor (TFT) substrate 100 and an opposing substrate 200 are bonded by a sealant 16 and liquid crystal is sandwiched thereinside. A display area14 is formed in the overlapped portion of the TFT substrate 100 and the opposing substrate 200. In the display area 14, scanning lines 11 extend in the horizontal direction (x direction) and are arranged in the vertical direction (y direction). Video signal lines 12 extend vertically and are aligned horizontally. Pixel 13 is formed in the area surrounded by the scanning lines 11 and the video signal lines 12.

In FIG. 1, the area where the TFT substrate 100 does not overlap with the opposite substrate 200 is a terminal area 15. The terminal area 15 is connected to a flexible wiring substrate 17 for supplying power and signals to a LCD panel. Driver integrated circuit (IC) that drives the LCD panel is mounted on the flexible wiring substrate 17.

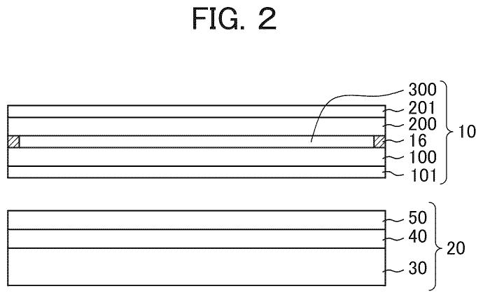

FIG. 2 is a cross-sectional view of the LCD display device. In FIG. 2, a backlight 20 is arranged behind the LCD panel 10. The LCD panel 10 has the following structure. The TFT substrate 100, on which the pixel electrodes, common electrodes, TFT, scanning lines, video signal lines, etc. are formed, is placed opposite to the opposing substrate 200, on which the black matrix and color filters are formed, and liquid crystal 300 is sealed thereinside.

Liquid crystal molecules are initially oriented by alignment films formed on the TFT substrate 100 and the opposite substrate 200. When voltage is applied between the pixel electrodes and the common electrode, the liquid crystal molecules rotate to form an image by controlling the light from the backlight 20 for each pixel. Since the liquid crystal 300 can only control deflected light, a lower polarizer 101 is placed under the TFT substrate 100 to allow only deflected light to enter the liquid crystal 300. The light modulated by the liquid crystal 300 is detected by an upper polarizer 201, and the image is viewed.

In FIG. 2, the backlight 20 is located behind the LCD panel 10. The backlight 20 consists of a color conversion sheet 40 placed above a light source 30 and an optical sheet group 50 placed above it. There are two types of the back light 20 for display devices: the side light type, in which a light source such as light emitting diodes (LEDs) is arranged on the side of a light guide plate, etc., and the direct-light type, in which a light source such as LEDs is arranged on the underside of the color conversion sheet 40, etc. In the present invention, a direct-light type backlight is used.

In FIG. 2, the color conversion sheet 40 is placed above the light source 30. The configuration of the color conversion sheet 40 will be explained later. Above the color conversion sheet 40 is the optical sheet group 50. Prism sheets, diffusion sheets, etc. are used for the optical sheet group 50. In addition, a deflection reflection sheet may be used to improve the efficiency of light utilization from the backlight 20. What kind of optical sheet is used or how many optical sheets are used is determined by the display device.

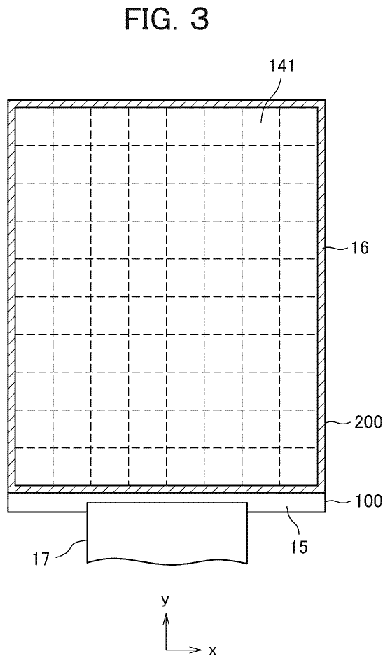

FIG. 3 depicts a plan view of the LCD panel 10 in which the display area is divided into 141 segments. The LEDs are arranged in the backlight for each of the 141 segments. FIG. 3 is a schematic diagram, and in reality, there are more segments than those depicted in FIG. 3. The size of each segment is less than 4 mm, often 2 mm. The dotted lines indicating segments in FIG. 3 are imaginary lines, and there are no such lines in the display area.

In FIG. 3, the LEDs, which are the light sources, are placed at the center of each segment. In other words, the LEDs are, viewed in a plane, arranged on the circuit board in a matrix with equal spacing in the x- and y-directions.

FIG. 4 is a plan view depicting four segments 141 depicted in FIG. 3. In FIG. 4, LED 31 is placed in the center of the segment 141. The LED 31 is approximately 100 to 300 μm in size when mini LEDs are used. In FIG. 4, the LED 31 is square, but it could be rectangular; the center to center spacing of the LED 31 is 2 mm, which is the same size as the segments.

The color conversion sheet 40 is arranged over the LEDs 31. One sheet is used as the color conversion sheet 40 for the common display area. The dotted line in FIG. 4 is an imaginary line indicating the boundary of the segment 141. Within the color conversion sheet, quantum dots (QDs) 41 mixed with red QDs 411, green QDs 412 and blue QDs 413 are dispersed, as explained in FIG. 5.

FIG. 5 is a cross-sectional view of the backlight configuration, corresponding to the A-A cross-sectional view of FIG. 4. In FIG. 5, the LED 31 is placed on a circuit substrate 33 for the backlight. The LED 31 is an ultraviolet light emitting diode (hereinafter referred to as UV LED). The LED 31 is covered by transparent resin 32. The transparent resin 32 is made of acrylic resin or silicone resin, for example.

In FIG. 5, the color conversion sheet 40 is placed on the transparent resin 32 covering the LEDs 31. The color conversion sheet 40 may use, as the color conversion material 41, a phosphor sheet in which phosphor particles are dispersed or a QD sheet in which QDs (hereinafter also referred to as quantum dots) are dispersed (hereinafter also referred to as quantum dot sheets). In FIG. 5, a QD sheet is used.

As depicted in FIG. 5, the color conversion sheet (QD sheet) 40 is a transparent binder 42 in which the quantum dots 41 are dispersed, sandwiched between thin transparent resin films 43 that also serves as a barrier layer. Acrylic, polycarbonate, or polyethylene terephthalate (PET) is used for the thin transparent resin film 43 as the barrier layer. The overall thickness of the color conversion sheet 40 is 80 to 300 microns.

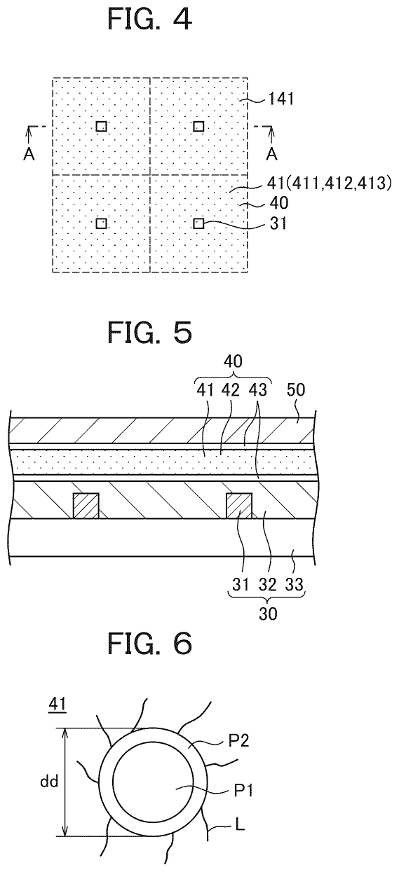

FIG. 6 is a schematic diagram of the quantum dots 41 used in FIG. 5. The Quantum dots 41 are semiconductor microparticles, and the wavelength of light that is converted and emitted differs depending on the size of the particle diameter. The diameter dd of the quantum dot 41 is generally less than 20 nm. In FIGS. 6, P1 and P2 are semiconductors; P1 is, for example, a spherical cadmium selenide (CdSe), and P2, which is zinc sulfide (ZnS), surrounds P1.

The quantum dots 41 confine incident light and emit light of longer wavelength than the incident light. The incident light is from the LED 31, which in this example is ultraviolet light. The L in the quantum dot 41 in FIG. 6 is a ligand, which facilitates dispersion of the quantum dot 41 in the resin. The quantum dots 41 depicted in FIG. 6 are dispersed in the transparent resin 42 called a binder. For example, silicone resin, epoxy resin, etc. can be used as the resin used as the binder 42.

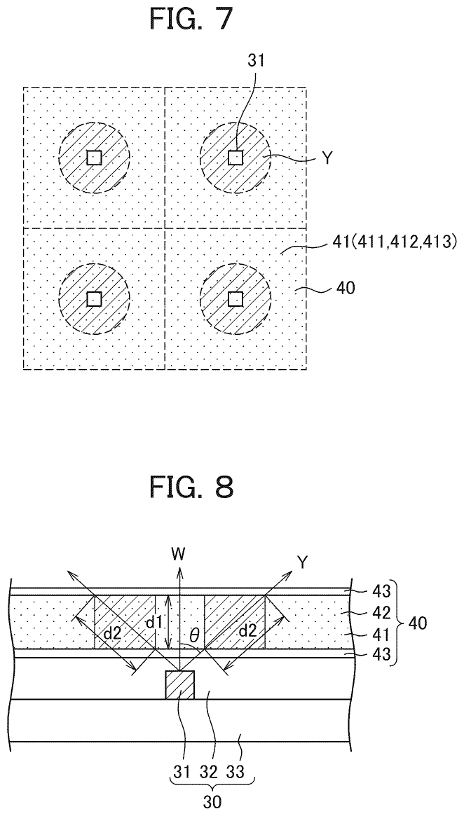

FIGS. 7 and 8 illustrate problems with the backlight depicted in FIGS. 4 and 5. FIG. 7 depicts the light emission pattern from the QD sheet 40 when the LED 31 is turned on in the same four segments as in FIG. 4. The configuration of FIG. 7 is the same as that in FIG. 4, with the color conversion sheet 40 placed above the LED 31. Ultraviolet light is emitted from the LED 31, some of which is converted into red light, green light, and blue light by the dispersed quantum dots in the QD sheet 40, resulting in white light as a whole, which is emitted from the QD sheet.

In reality, however, the absorption rate of the ultraviolet light and the conversion efficiency of the ultraviolet light into the red light, the green light, and the blue light differ depending on the red quantum dot 411 that absorbs the ultraviolet light and emits the red light, the green quantum dot 412 that absorbs the ultraviolet light and emits the green light, and the blue quantum dot 413 that absorbs the ultraviolet light and emits the blue light. Therefore, in general, the amount of the red quantum dot 411, the green quantum dot 412, and the blue quantum dot 413 are adjusted so that the light emitted directly above the LED is white.

However, the fact that each quantum dot has a different absorption rate of the ultraviolet light and conversion efficiency of the ultraviolet light to visible light means that the balance of the red, green, and blue emitted light will differ depending on the optical path difference of the ultraviolet light. For example, if the conversion efficiency of the blue quantum dots is lower than that of the other quantum dots, as depicted in FIG. 7, a yellow region, which is indicated by Y, is generated around the LED 31. This region is, for example, the hatched ring in FIG. 7.

FIG. 7 is a schematic diagram, and a yellow shift region does not have a clear boundary. The dotted ring in FIG. 7 indicates the approximate area where a yellow shift occurs. In other words, in FIG. 7, the area corresponding to the LED 31 is white, the hatched area is yellow-shifted, and the area further outside the hatched area is white again.

FIG. 8 depicts a cross-sectional view of one segment of the backlight. In FIG. 8, the optical sheet group is omitted. In FIG. 8, the UV LED 31 is placed on the circuit substrate 33, and the transparent resin 32 covers the UV LED 31. The QD sheet 40 is placed over the transparent resin 32; the QD sheet 40 consists of the quantum dots 41 dispersed in the binder 42, which is sandwiched between the transparent barrier layers 43.

As depicted in FIG. 8, light traveling in the normal direction of the QD sheet 40 from the LED 31 and light traveling at an angle θ with the normal direction differ in the distance they travel in the QD sheet 40. The distance that the light traveling in the normal direction travels in the QD sheet 40 is d1, and the distance that the light traveling at an angle θ with respect to the normal direction travels in the QD sheet 40 is d2, where d2>d1.

In other words, the light traveling at an angle θ with respect to the normal direction has a greater probability of being captured by the quantum dots 41, and therefore, the difference in the probability of the ultraviolet light being converted to each color light is greater. As depicted in FIG. 8, when the area directly above the LED 31 is set to white light W of the desired color temperature, for example, if the conversion efficiency of the blue quantum dot is lower than that of the other quantum dots, light Y passing through the hatched area in FIG. 8 will cause the yellow shift. In FIG. 8, the arrow W is the white light and Y is the yellow-shifted light.

This phenomenon depends on the value of the angle θ. It becomes noticeable to the human eye when the angle θ is larger than a certain value. On the other hand, when the angle θ becomes very large, the amount of the ultraviolet light becomes small and the imbalance of each color becomes less noticeable. Therefore, the phenomenon of the outgoing light returning to white occurs. In other words, of the light from the LED 31 that travels at an angle θ with the normal direction of the QD sheet 40, the light with a certain range of angle θ is yellowish.

FIGS. 7 and 8 depict the case where the luminous efficiency of the blue quantum dot 413 is lower than that of the red quantum dot 411 and the green quantum dot 412.

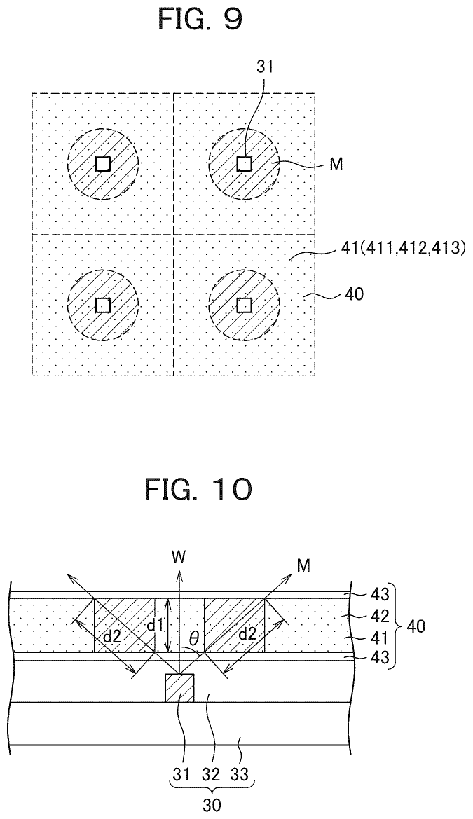

FIGS. 9 and 10 are cases where the luminescence efficiency of the green quantum dot 412 is lower than the luminescence efficiency of the red quantum dot 411 and the blue quantum dot 413. In this case, as depicted in FIG. 9, the region around the UV LED 31 produces an area tinged with magenta, namely, a magenta shift. In FIG. 9, this region is indicated by M.

FIG. 10 is a cross-sectional view of FIG. 9. In FIG. 10, the light directly above the LED 31 is the white light indicated by arrow W, while the light emitted from the LED 31 at angle θ produces the magenta shift, as indicated by arrow M. In FIG. 10, this light is represented by M.

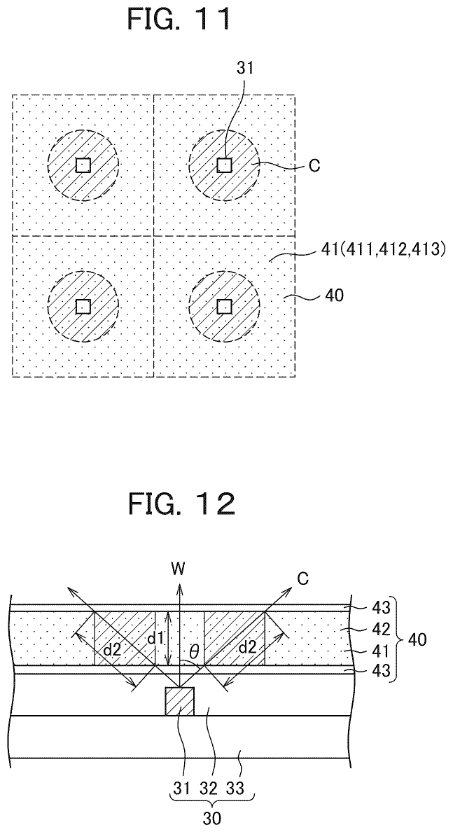

FIGS. 11 and 12 depict a case where the luminous efficiency of the red quantum dot 411 is lower than that of the green quantum dot 412 and the blue quantum dot 413. In this case, as depicted in FIG. 11, the region around the UV LED 31 produces a cyan shift with cyan color tinged. In FIG. 11, this region is indicated by C.

FIG. 12 is a cross-sectional view of FIG. 11. In FIG. 12, the light directly above the LED 31 is the white light as indicated by the arrow W, while the light emitted from the LED 31 at an angle θ produces the cyan shift, as indicated by the arrow C. In FIG. 12, this light is represented by C.

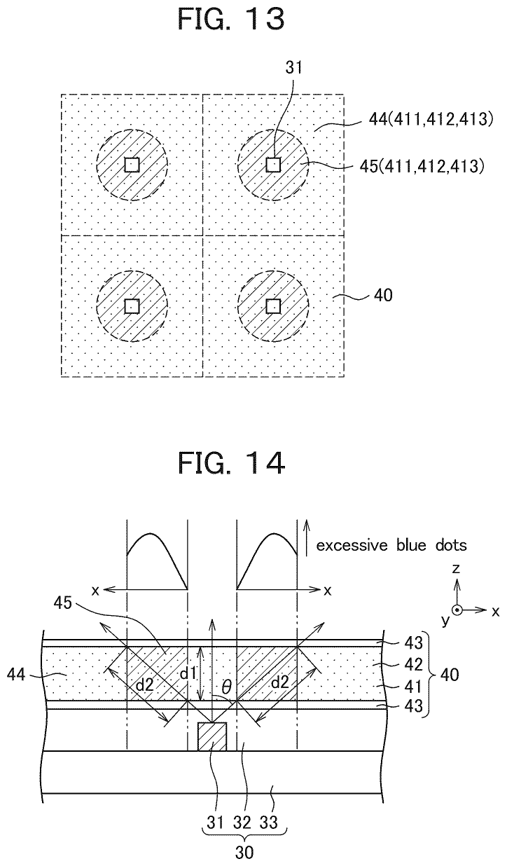

The present invention solves the above problems. FIG. 13 is a plan view of the configuration depicted in FIGS. 7 and 8, which measures the case where the area around the LED 31 produces the yellow shift, and depicts the features of Embodiment 1. FIG. 13 is a plan view of the four segments corresponding to FIG. 7. In FIG. 13, the UV LED 31 is located in the center of the segment, and the QD sheet 40 is arranged over the UV LED 31. A region 45, in which the proportion of the blue quantum dots 413 is larger than that in a region 44. This region 45 is formed in the shape of a ring surrounding the ultraviolet LED 31 when viewed in a plane view.

The region 45 in FIG. 13 corresponds to the ring-shaped hatched area depicted in FIG. 7, i.e., the area that causes the yellow shift. In other words, since the yellow shift is a phenomenon caused by low blue light, this phenomenon can be reduced by increasing the number of the blue quantum dots 413 in this region.

FIG. 14 is a cross-sectional view of FIG. 13. In FIG. 14, the QD sheet 40 consists of the region 44 and the hatched region 45, while the regions 44 and 45 are as described in FIG. 13. The region 45 is the area where more of the blue quantum dots 413 are dispersed than the other quantum dots. The increment of the blue quantum dots 413 in the region 45 may be constant within the region 45, but it may be better to have a distribution.

The upper distribution diagram in FIG. 14 depicts the incremental amount of the blue quantum dots 413 in the region 45, which is indicated by hatching. As depicted in FIG. 14, the increment of the blue quantum dot 413 varies smoothly within the region 45, but the peak exists outside the center of the ring-shaped region 45 in the width direction. By varying the increment of the blue quantum dots 413, the yellow shift can be corrected more accurately.

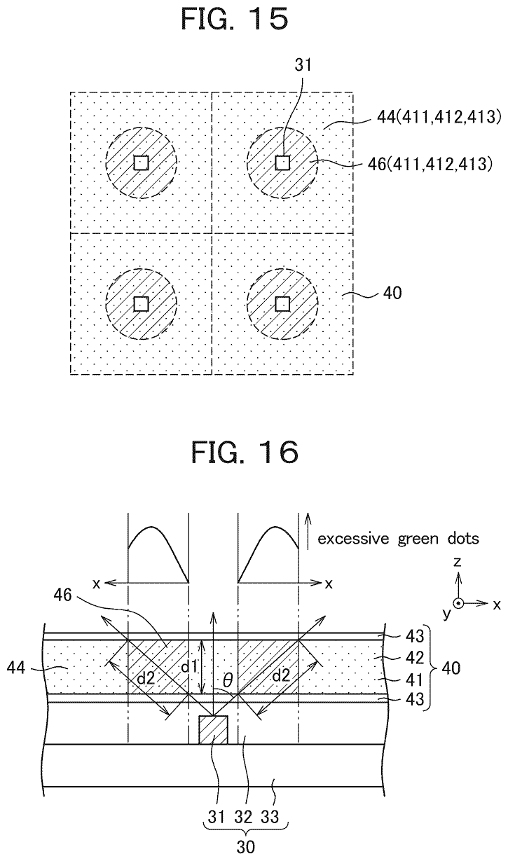

However, the distribution depicted in FIG. 14 is just an example, and various other distributions can be used. The range 45 where the percentage of the blue quantum dots 413 is larger than that in the other areas is a radius of d/4 or less, when the distance between the UV LEDs 31 and the UV LEDs 31 is d. In other words, the range 45 where the percentage of the blue quantum dots 413 is larger than that in the other areas is a radius of d/4 or less. This is because, in the area above d/4, the yellow shift phenomenon depicted in FIG. 7 becomes less pronounced. The distribution explained above is the same for FIGS. 15 through 18.

FIG. 15 is the configuration depicted in FIGS. 9 and 10 to counter the case where the area around LED 31 produces the magenta shift. FIG. 15 is almost the same configuration as that described in FIG. 13. The difference between FIG. 15 and FIG. 13 is that, in a ring-shaped region 46 depicted in hatching, there are more of the green quantum dots 412 than in the other region 44. The operation of FIG. 15 is the same as that described in FIG. 13.

FIG. 16 is a cross-sectional view of FIG. 15. In FIG. 16, QD sheet 40 consists of the region 44 and the hatched region 46. The difference between FIG. 16 and FIG. 14 is the presence of the region 46, i.e., the region 46 with the large number of green quantum dots 412. The presence of the region 46 reduces the magenta shift. The distribution of the green quantum dots 412 is also the same as that described in FIG. 14. Other operations in FIG. 16 are also the same as that described in FIG. 14.

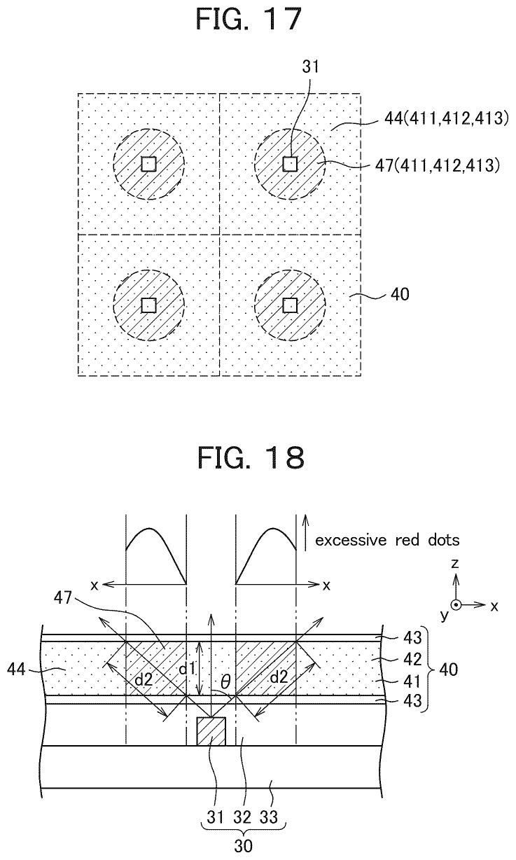

FIG. 17 is the configuration depicted in FIGS. 11 and 12 to counter the case where the area around the LED 31 produces the cyan shift. The configuration in FIG. 17 is almost the same as the configuration described in FIG. 13. The difference between FIG. 17 and FIG. 13 is that, in a ring-shaped region 47 depicted in hatching, there are more of the red quantum dots 411 than in the other regions 44. The operation of FIG. 17 is the same as that described in FIG. 13.

FIG. 18 is a cross-sectional view of FIG. 17. In FIG. 18, the QD sheet 40 consists of the area 44 and the hatched area 46. The difference between FIG. 18 and FIG. 14 is the presence of the region 47, in which more of the red quantum dots 411 exist than in other regions. The presence of region 47 reduces the cyan shift. The distribution of red quantum dots 411 is also the same as that described in FIG. 14. The other operations in FIG. 18 are also the same as that described in FIG. 14.

### Embodiment 2

In Embodiment 1, the configuration is that a region with the many blue quantum dots 413, green quantum dots 412, or red quantum dots 411 is formed in the area where the yellow shift, the magenta shift, or the cyan shift is generated. In other words, from the center to the boundary where the LED 31 exists, the distribution does not form a region with a large number of each quantum dot. However, limiting the quantum dots to such a region may be difficult in the process. In Embodiment 2, the distribution of the quantum dots is smoothed by having a very small amount of quantum dot-rich regions exist, rather than zero, even in the area corresponding to the LED 31. The actual action is the same as that described in Embodiment 1.

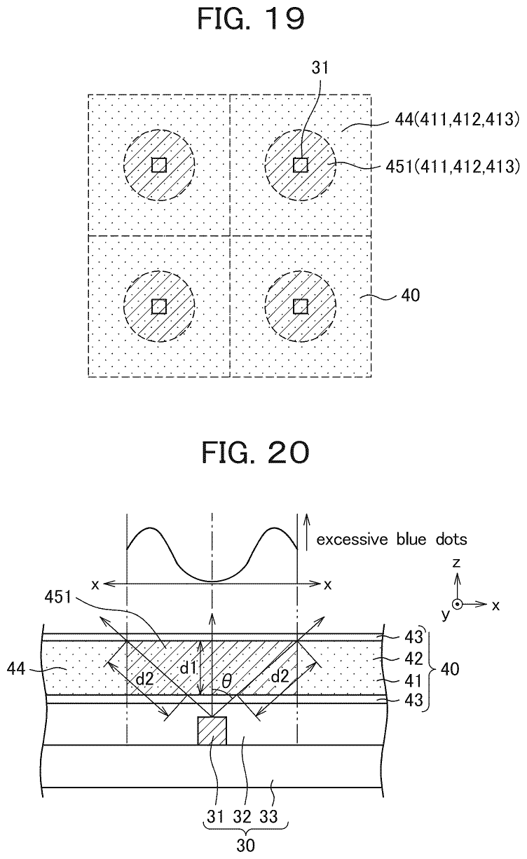

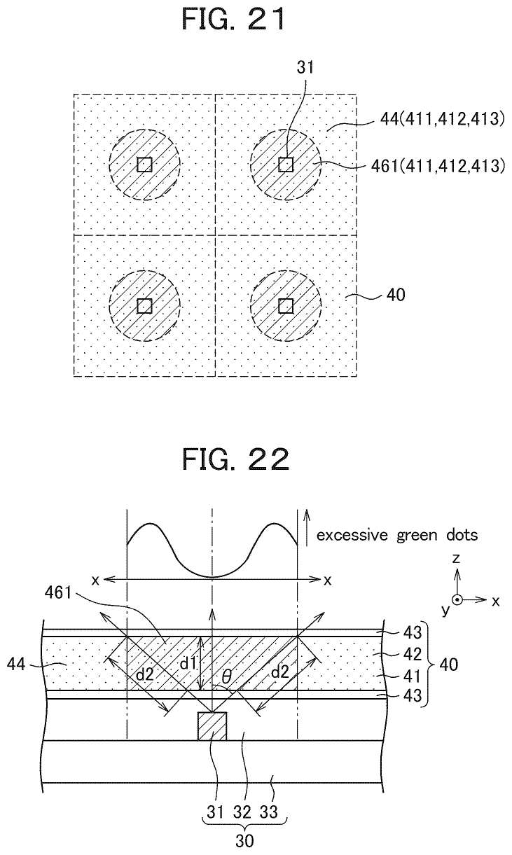

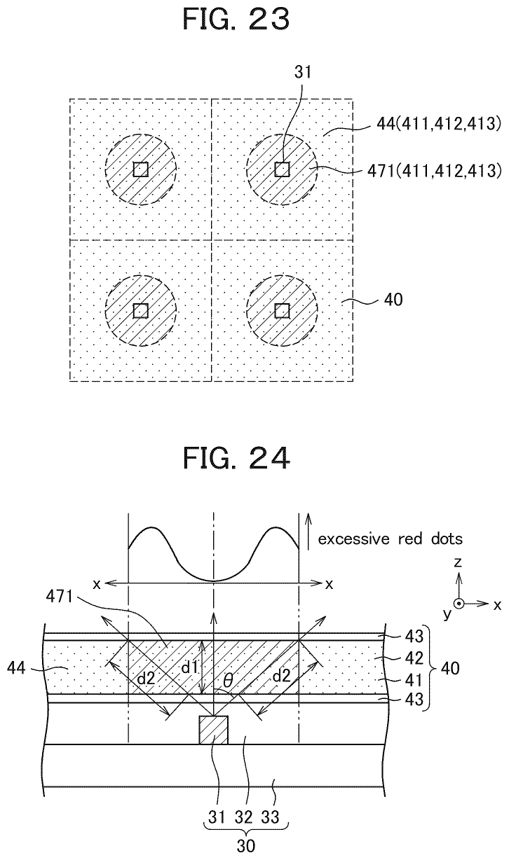

For example, in FIGS. 19 and 20, a circular region 451 is the area with the more of the blue quantum dots 413. The radius of this circular region 451 is less than ¼ of the distance between the UV LEDs 31 and the UV LEDs 31. The peak of the distribution of the blue quantum dots 413 in the region 451 is located outside of half of the radius of the circular region. The same is true in FIGS. 21 and 22, as well as FIGS. 23 and 24.

FIGS. 19 and 20 are variations of FIGS. 13 and 14. The difference between FIGS. 19 and 20 and FIGS. 13 and 14 is that, in the QD sheet 40, there is a region 452 where the blue quantum dots 413 are incremented, although the increment is very small, even in the portion corresponding to the UV LED 31 when viewed in a plane. However, this difference is to facilitate the dispersion process of the quantum dots, and the action is substantially the same as that described in FIGS. 13 and 14.

FIGS. 21 and 22 are variations of FIGS. 15 and 16. The difference between FIGS. 21 and 22 and FIGS. 15 and 16 is that, in the QD sheet 40, there is a region 461 where the green quantum dots 412 are incremented, although the increment is very small, even in the portion corresponding to the UV LED 31 when viewed in a plane view. However, this difference is to facilitate the dispersion process of the quantum dots, and the action is substantially the same as that described in FIGS. 15 and 16.

FIGS. 23 and 24 are variations of FIGS. 17 and 18. The difference between FIGS. 23 and 24 and FIGS. 17 and 18 is that, in the QD sheet 40, there is a region 471 where the red quantum dots 411 are incremented, although the increment is very small, even in the portion corresponding to the UV LED 31 when viewed in a plane view. However, this difference is to facilitate the dispersion process of the quantum dots, and the action is substantially the same as that described in FIGS. 17 and 18.

Thus, the distribution of the quantum dots 41 is only slightly different between Embodiment 1 and Embodiment 2, and in either configuration, the yellow shift, the magenta shift, and the cyan shift can be reduced in the same manner.

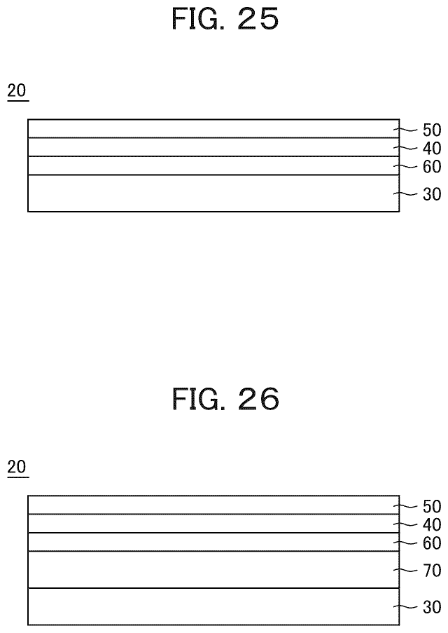

Embodiment 1 and Embodiment 2 described the configuration of the backlight 20 depicted in FIG. 2. However, the present invention can be applied to various backlights other than the backlight depicted in FIG. 2. The backlight of FIG. 25 is an example in which a dichroic sheet 60 is placed between the light source 30 and the QD sheet 40, in addition to the configuration of the backlight of FIG. 2. The backlight of FIG. 26 is an example in which a polycarbonate plate 70 is placed between the light source 30 and the dichroic sheet 60 in addition to the configuration of FIG. 25. Since the polycarbonate plate 70 has a very high transmittance, it can be used instead of placing a space between the light source and the dichroic sheet or other sheets.

In the above explanation, the QD sheet 40 uses the quantum dots 41, but instead of the QD sheet 40, a color conversion sheet using phosphors can be used. In this case, red phosphors correspond to red quantum dots, green phosphors correspond to green quantum dots, and blue phosphors correspond to blue quantum dots.

What is claimed is:

1. A display device comprising a display panel and a backlight,
the backlight including a light source in which ultraviolet light emitting diodes are arranged in a plane and in a matrix with a first spacing, and a color conversion sheet covering the light source,
the color conversion sheet being dispersed with red quantum dots that emit red when exposed to ultraviolet light, green quantum dots that emit green when exposed to the ultraviolet light, and blue quantum dots that emit blue when exposed to the ultraviolet light,
the color conversion sheet having a first region and a second region arranged in a ring shape to surround the ultraviolet light emitting diode, viewed in plan view,
in the second region, more of the red quantum dots, the green quantum dots, or the blue quantum dots being dispersed than in the first region.

2. The display device according to claim 1, wherein, in the second region, the red quantum dots are dispersed more than in the first region.

3. The display device according to claim 1, wherein, in the second region, the green quantum dots are dispersed more than in the first region.

4. The display device according to claim 1, wherein, in the second region, the blue quantum dots are dispersed more than in the first region.

5. The display device according to claim 1, wherein an outer radius of the ring is equal to or less than ¼ of the first spacing.

6. The display device according to claim 1, wherein any of the red quantum dots, the green quantum dots, or the blue quantum dots in the second region have a distribution, and a peak of the distribution is located outside of a center of a width of the ring.

7. A display device comprising a display panel and a backlight,
the backlight including a light source in which ultraviolet light emitting diodes are arranged in a plane and in a matrix with a first spacing, and a color conversion sheet covering the light source,
the color conversion sheet being dispersed with red quantum dots that emit red when exposed to ultraviolet light, green quantum dots that emit green when exposed to the ultraviolet light, and blue quantum dots that emit blue when exposed to the ultraviolet light,
the color conversion sheet having a first area and a second area arranged in a circular pattern to cover the ultraviolet light emitting diode, viewed in plan view,
in the second region, more of the red quantum dots, the green quantum dots, or the blue quantum dots being dispersed than in the first region.

8. The display device according to claim 7, wherein, in the second region, the red quantum dots are dispersed more than in the first region.

9. The display device according to claim 7, wherein, in the second region, the green quantum dots are dispersed more than in the first region.

10. The display device according to claim 7, wherein, in the second region, the blue quantum dots are dispersed more than in the first region.

11. The display device according to claim 7, wherein, a radius of the circle is equal to or less than ¼ of the first spacing.

12. The display device according to claim 7, wherein the red quantum dots, the green quantum dots, or the blue quantum dots in the second region have a distribution, and a peak of the distribution exists outside of ½ of the radius of the circle.
